(19) United States
(12) Patent Application Publication
(10) Pub. No.: US 2009/0067487 A1
(43) Pub. Date: Mar. 12, 2009

(54) INCREASING PWM RESOLUTION BY MODULATION

(75) Inventor: Horst Diewald, Freising (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 12/208,864

(22) Filed: Sep. 11, 2008

Related U.S. Application Data
(60) Provisional application No. 61/016,940, filed on Dec. 27, 2007.

(30) Foreign Application Priority Data
Sep. 12, 2007 (DE) 10 2007 043 340.0

(51) Int. Cl. H03K 7/08

(52) U.S. Cl. 375/238

(57) ABSTRACT

A method for generating a pulse width modulated (PWM) signal includes determining a PWM period and/or a pulse width of the pulse width modulated signal by counting the number of clock cycles of a reference clock signal and by switching the pulse width modulated signal when a predetermined number of clock cycles is reached. The reference clock signal comprises clock cycles of at least a first clock period and a second clock period. The first clock period and the second clock period differ by an amount of time, which is substantially smaller than both half of the first clock period and half of the second clock period.

This patent application claims priority from German Patent Application No. 10 2007 043 340.0, filed 12 Sep. 2007, and from U.S. Provisional Patent Application No. 61/016,940, filed 27 Dec. 2007, the entireties of which are incorporated herein by reference.

### FIELD OF THE INVENTION

The invention relates to a method for generating a pulse width modulated signal, and to an electronic device including circuitry for generating a pulse width modulated signal.

### BACKGROUND

Pulse width modulation (PWM) is a widespread signal modulation method used for all kinds of control and data communication applications. These applications include, for example, switched mode power supplies, digital motor control and many other applications. The pulse width modulated signal alternates between a high level and a low level, wherein the pulse width is the time during which the signal is switched on (or in the high level state). The time between two rising edges of the pulse width modulated signal is referred to as the period of the pulse width modulated signal. The ratio between the pulse width and the period is a significant measure for pulse width modulated signals. If a pulse width modulated signal is used, the ratio of the pulse width to the period is varied in order to perform a specific control task or to include specific information in the signal.

There are basically three ways to adapt the ratio between pulse width and period: increasing or decreasing the pulse width; increasing or decreasing the period; and changing both the period and the pulse width. The step size or resolution in which the pulse width and the period can be adapted is an important characteristic of the range and the precision of the pulse width modulated signal. The maximum accuracy of the resolution is limited by, for example, the technical capabilities of the available technology, the feature set of the available components and by commercial considerations relating to complexity and costs for a specific device. The period or the PWM frequency is basically determined by a specific application and criteria such as a required frequency range, filtering and corresponding components, or response behavior to changing system conditions. The pulse width, as part of the duty cycle and its required resolution, are basically defined based on the system's accuracy. The required resolution defines the number of steps in which the pulse width can be selected or, in other words, it defines the minimum change of the pulse width.

In view of the above mentioned constraints, the engineer usually conceives a specific circuit for providing a required resolution or other property. If, for example, the PWM frequency is 44 kHz and an 8-bit resolution is required, the system clock must be greater than 44 kHz*28=11264 kHz. As apparent from this example, in order to provide a specific resolution for a given frequency of the PWM signal, the required system clock must be substantially greater than the PWM frequency. If, for example, the pulse width resolution must be 200 ns, and the PWM frequency is 20 kHz, the length of the pulse width modulated signal in terms of steps can be calculated as follows: length_{PWM}=f_{PWM}×t_{pulsewidth}=1/(20*10³×200*10⁻⁹)=1/(4*10⁻³)=250 [Steps].

The previous examples relate to conventional approaches, which can be easily implemented in today's semiconductor technologies. However, other examples place much higher requirements on the technology and results in a resolution of 1 ns. For example, if the PWM frequency is 100 kHz and the resolution is 10 Hz, then the system clock must be equal or greater than 1000 MHz (=1 GHz). Frequencies as high as 1 GHz are even more difficult to implement, and generally not acceptable for most applications from a commercial point of view.

### SUMMARY

It is an object of the invention to provide a method for generating a pulse width modulated signal and a corresponding electronic device implementing the method, which eases the technical requirements while providing a high resolution for pulse width modulated signals.

According to a first aspect of the invention, a method for generating a pulse width modulated signal is provided, which includes the steps of determining a period and/or a pulse width of the pulse width modulated signal by counting the number of clock cycles of a reference clock signal and by switching the pulse width modulated signal when a predetermined number of clock cycles is reached. The reference clock signal includes clock cycles of at least a first clock period and a second clock period, the first clock period and the second clock period differing by an amount of time which is substantially smaller than both half of the first clock period and half of the second clock period.

The invention is based on the realization that most of the applications, such as switch-mode power supplies, lamp ballast, or digital audio amplifier can use modulated PWM signals as long as the modulation PWM frequency is high enough to be reduced (e.g., by filtering) to an acceptable level. The filter used in those systems will usually eliminate the PWM or modulation frequency, which is used to get high resolution with much lower speed and power requirements to the basic PWM scheme. Accordingly, it is possible to use a reference clock, which is based on two different clock frequencies or two different clock cycles (the first clock cycle and the second clock cycle) which have two different clock periods.

The difference between the clock periods is very small compared to the clock period of either of the two clock signals. By counting the number of clock cycles of the reference clock, a specific period of time is defined, after which the pulse width modulated signal can be switched from one level to the other. Changing the basic clock period of the reference clock changes the amount of time needed to reach a specific number of clock cycles. If the two clock periods (the first clock period and the second clock period) differ by a certain Δt, the reference clock can be composed of a specific sequence of clock cycles having either the first clock period or the second clock period, such that a specific pulse width and a specific period of the pulse width modulated signal is provided. In order to increase the pulse width to period ratio, it is possible to increase the number of clock cycles having the second clock period and decreasing the number of clock cycles having the first clock period. For each substitution of a clock cycle having the first clock period by a clock cycle having the second clock period, the length over all clock cycles is increased (or decreased) by Δt.

There are many different ways to implement the mechanism to change between clock cycles of the first clock period and clock cycles of the second period. Generally, a clock generation stage can be tuned by an analog or a digital input signal between two clock frequencies. As long as the transient between the two frequencies is fast enough, the counting means used to count the number of clock cycles of the reference clock will not be aware of the transient. The reference clock signal can also be composed of two different clock signals, which will be explained in more detail below.

If the difference between the two clock periods Δt is chosen to be very small, it is possible to provide a very fine resolution, although the basic clock periods (the first and the second clock periods) of the reference clock signal are much greater. If, for example, the first clock period amounts to 20 ns and the second clock period amounts to 21 ns, the difference between the two clock periods Δt is only 1 ns. The resolution, which can be achieved by this configuration, is 1 ns, although the reference clock is lowered by a factor of 20. Accordingly, the requirements relating to the technology, and in particular, to the speed of the specific semiconductor technology used to implement the circuitry, is substantially reduced. As it is much easier to generate two periods with a Δt of 1 ns instead of using the clock frequency of 1 GHz, the technological limitations are overcome. Further, as there is no clock signal with a frequency as high as 1/Δt, a considerable amount of power can be saved.

According to another aspect of the invention, the method includes further generating a first clock signal having the first clock period, generating a second signal having the second clock period, and composing the reference clock signal by using at least one clock cycle of both, the first clock signal and one clock cycle of the second clock signal. Accordingly, there are two different clock signals and the reference clock signal is composed by switching between the clock signals in order to provide clock cycles having the first clock period or the second clock period. If switching between two constant clock signals instead of tuning a single clock signal is easy and less complex to implement, this approach is to be preferred.

According to another aspect of the invention, at least one clock cycle of the first period and one clock cycle of the second period is used within one period of the pulse width modulated signal. The composition of the reference clock signal based on two different clock signals having different clock frequencies can be carried out over multiple periods or a single period of the pulse width modulated signal. The number of clock cycles having the first clock period and number of clock cycles having the second clock period can selectively and variably be chosen over a plurality of periods of the pulse width modulated signal, such that the pulse width of the pulse width modulated signal is averaged over a plurality of clock periods of the pulse width modulated signal. The number of clock cycles of the first clock period in a number of clock cycles of the second clock period can also be periodically varied over a modulation period. All this relates to the numerous different ways of composing clock cycles with a first clock period and clock cycles with the second clock period. The number of clock cycles of the first or of the second period, which can be included within one period of the pulse width modulated signal, is limited. Accordingly, the range, over which the specific resolution depending basically on the difference between the first and the second clock period is also restricted. Therefore, it can be necessary to average over multiple periods in order to realize specific steps or a specific resolution for the pulse width. Basically, it is possible to modulate the period of the PWM signal using a constant pulse width, to modulate the pulse width while maintaining a constant period, or to modulate both the period and the pulse width. All this can also be done over single or multiple periods of the pulse width modulated signal in order to average out a specific pulse width. For example, it is possible to compose the different clock periods of the two clock signals such that a specific length of a pulse width is achieved. In this situation, the complete clock period is chosen to be sufficiently long, such that the ratio between the pulse width and the time during which the pulse is switched off is averaged by a specific factor.

According to another aspect of the invention, an electronic device is provided, which includes circuitry for generating a pulse width modulated signal. The circuitry includes a counter adapted to be increased in response to a reference clock signal, a comparator for comparing the count of the counter to a predefined number, a logic circuitry coupled to the counter output and to the comparator for producing the pulse width modulated signal, and switching means for switching the clock cycles of the reference clock signal between first clock cycles having a first clock period and second clock cycles having a second clock period. The first clock period and the second clock period differ by an amount of time, which is substantially smaller than both half of the first clock period and half of the second clock period. Further, the electronic device can include controlling means adapted to control the switching mechanism. Also, the electronic device may include means for generating the first clock signal having the first clock period and generating the second clock signal having the second clock period, as well as means for setting the first clock signal having the second clock period, as well as means for setting the first clock period and the second clock period to differ by the amount of time which is substantially smaller than both half of the first clock period and the half of the second clock period. An electronic device implemented as set out here above, is capable of implementing the method according to the invention, thereby providing a mechanism which is suitable to overcome the technical limitations of any technology in terms of jitter, phase noise, speed and the like.

### BRIEF DESCRIPTION OF THE DRAWINGS

Further features and advantages of the invention will be apparent from the following description of example embodiments, with reference to the accompanying drawings, wherein:

FIG. 1 shows a block diagram and a waveform, which illustrate the basic principle of pulse width modulation;

FIG. 2 shows an example of a counter based PWM generating stage;

FIG. 3 shows a waveform of a pulse width modulated signal illustrating the modulation period;

FIG. 4 shows a block diagram of a first preferred embodiment of the invention;

FIG. 5 shows waveforms relating to a second embodiment of the invention; and

FIG. 6 shows a waveform relating to a third embodiment of the invention.

### DETAILED DESCRIPTION OF EXAMPLE EMBODIMENTS

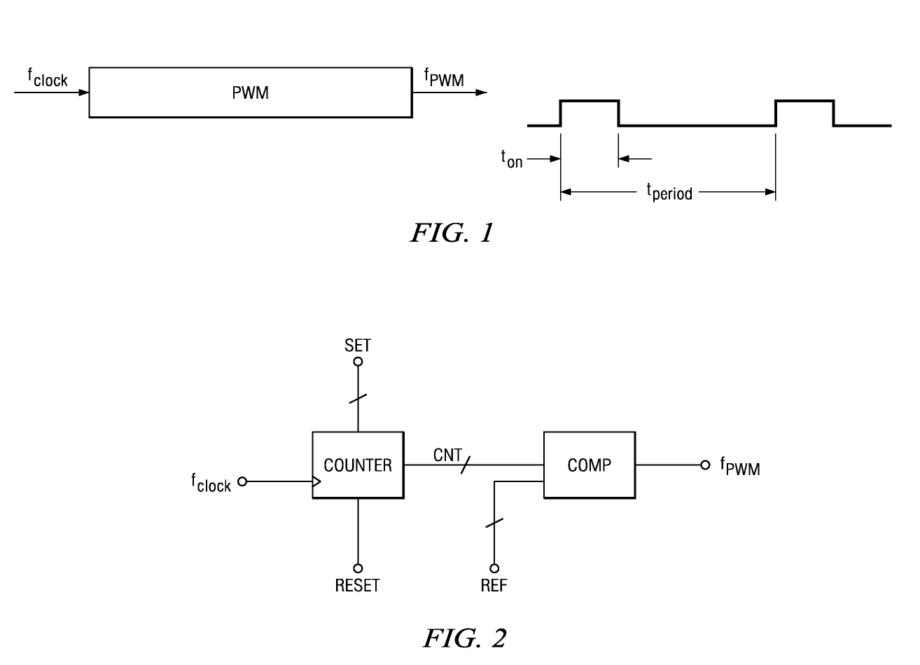

FIG. 1 shows a basic block diagram of a PWM generation stage PWM. The system clock f_{clock} is used for an internal counter in the PWM stage. The counter counts the edges or clock cycles of the system clock f_{clock} and produces a corresponding output signal f_{PWM} having a specific pulse width tₒₙ and a period t_{period}. If the internal counter in the PWM generation stage reaches a predefined specific number count, the output signal is switched from high to low. When the period of the pulse width modulated signal t_{period} has elapsed, the counter is reset and starts anew with counting the clock cycles of the system clock f_{clock}. In order to change the ratio of the pulse width tₒₙ and the period t_{period}, a specific logic is implemented, in order to change the predefined number (e.g. the maximum clock count) and additional logic to generate the respective pulse width modulated output signal. Typically, there is a comparator for comparing the clock count to the predefined number. Further, there can be an additional comparator comparing the clock count to another number representing the length of the pulse width period t_{period}.

FIG. 2 shows a simplified block diagram of circuitry that may be used in the PWM stage shown in FIG. 1. The system clock signal f_{clock} is input to a counter COUNTER, which can be reset and set by respective signals SET and RESET. The count CNT of the counter is increased or decreased by 1 for each edge (or both edges) of the system clock signal f_{clock} and passed to a comparator COMP, which compares the count CNT to a reference value REF and generates an output signal f_{PWM} in accordance with the comparison result. The COUNTER is capable of counting forwards and backwards, and the reference value REF can also be zero. The COUNTER is used to determine the period of the PWM output signal and/or the pulse width of the PWM signal. Also, two counters and two comparators can be provided to define the period and the pulse width. Additional logic circuitry can be included, and preferably, is included in the comparator COMP in order to correctly provide a pulse width modulated output signal f_{PWM}.

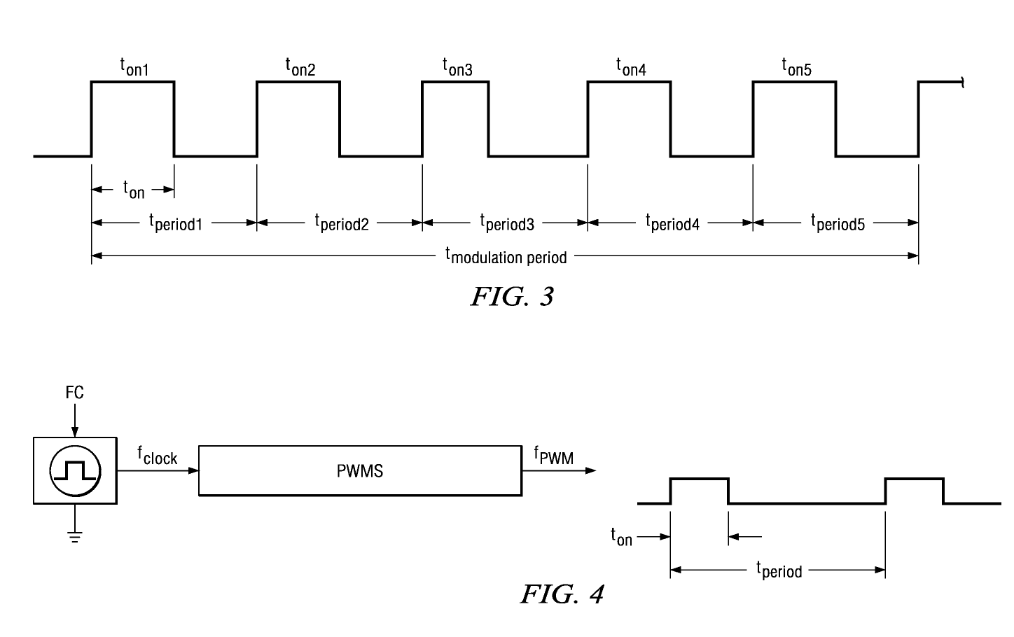

FIG. 3 shows a waveform illustrating a typical modulation sequence of a pulse width modulated signal. The pulse widths tₒₙ₁, tₒₙ₂, tₒₙ₃, tₒₙ₄ and tₒₙ₅ are varied, while the periods t_{period1}, t_{period2}, t_{period3}, t_{period4} and t_{period5} remain constant. Accordingly, over the whole modulation period t_{modulation period} the ratio between the pulse width tₒₙ and the pulse period t_{period} is varied in order to control a specific device or to communicate a specific information content.

FIG. 4 shows a simplified block diagram of a first embodiment of the invention. Accordingly, a frequency control signal FC is used to control an oscillator or a similar clock signal generation stage for generating a system clock f_{clock}. The system clock f_{clock} is fed to the PWM stage PWMS, which produces a pulse width modulated output signal f_{PWM}. The frequency of the system clock f_{clock} can be varied by the control signal FC, thereby slowing down or accelerating the counter internal to the PWMS stage. In accordance with the frequency (e.g., the clock periods) of the system clock f_{clock} used to clock the counter, the predefined number, which is also internal to the PWMS stage, is achieved either sooner or later compared to a constant system clock f_{clock}. Accordingly, it is possible to produce ratios of pulse widths and periods with an increased resolution.

For example, the first clock may have a first clock period of t_{cycle1}=20 ns and the clock period of the second clock signal may be t_{cycle2}=21 ns. For a pulse width of tₒₙ≧400 ns, a seamless resolution of 1 ns is possible. The lower limit for tₒₙ is given by tₒₙ≧(t_{cycle1}*t_{cycle1})/(t_{cycle2}−t_{cycle1})=(20 ns*20 ns)/(21 ns−20 ns)=400 ns. The pulse width can be composed as follows: tₒₙ=7*t_{cycle2}+13*t_{cycle1}=7*21 ns+13*20 ns=407 ns. For a pulse width of 408 ns, it is possible to substitute another clock cycle of the first clock t_{cycle1} by a clock cycle of the second clock t_{cycle2}, which would give the following pulse width tₒₙ=8*t_{cycle2}+12*t_{cycle1}=408 ns. The complete period from one rising edge to another rising edge of the pulse width modulated signal can be calculated as the remaining part of the period from which the pulse width tₒₙ is subtracted. This can be implemented by a second counter (like the one shown in FIG. 2), the count of which is always increased by use of only one clock signal (e.g., the first clock t_{cycle} having the first clock period t_{cycle1}).

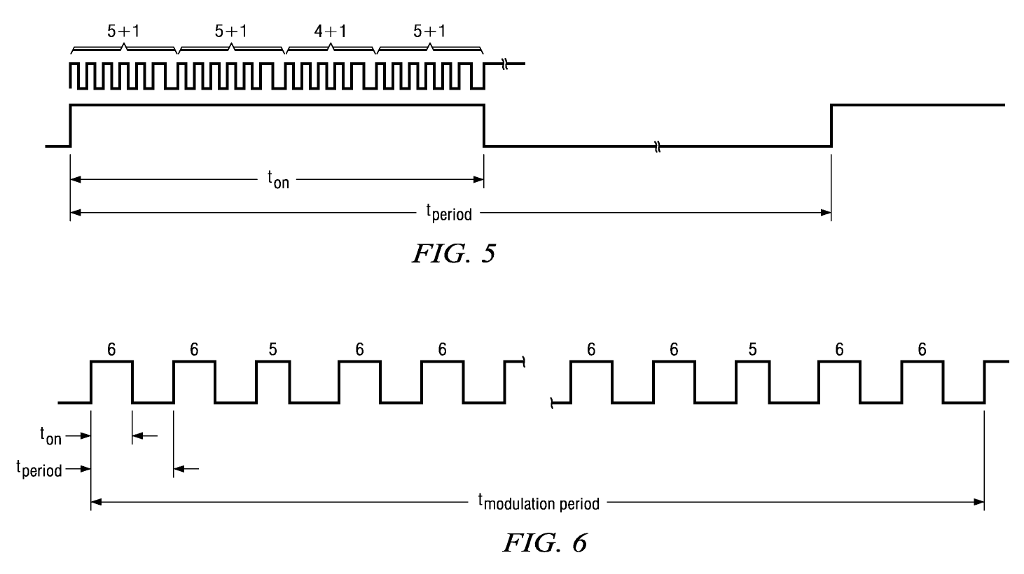

As shown in FIG. 5, it is possible to integrate over multiple periods of the PWM signal in order to produce pulse widths representing shorter lengths than achievable by merely combining the first and the second clock signals. As for the previous example, the first clock period can be t_{cycle1}=20 ns and the second clock period can be t_{cycle2}=21 ns. A pulse width of tₒₙ=116 ns can be achieved by a pulse width of tₒₙ=464 ns, if only one such period is integrated over a total time corresponding to four complete periods (i.e., 464 ns={121 ns+121 ns+101 ns+121 ns). Accordingly, tₒₙ=(5*t_{cycle1}+1*t_{cycle2})+(5*t_{cycle1}+1*t_{cycle2})+(4*t_{cycle1}+1*t_{cycle2})+(5*t_{cycle1}+1*t_{cycle2})=19*20 ns+4*21 ns=464 ns. For the definition of the pulse width, it is also possible to use more than two individual clock frequencies (clock cycles). The modulation scheme can use the different frequencies in a sequence or mixed. Mixing the clock frequencies will reduce the error or ripple of the pulse width modulated signal.

Another example for a long modulation period t_{modulation period} is shown in FIG. 6. According to this embodiment of the invention, the pulse width tₒₙ of the PWM signal can be modulated while the PWM period is kept constant. An average pulse width of 116 ns corresponds to a total pulse width of 2320 ns over 20 periods. tₒₙ=4*(6*t_{cycle}+6*t_{cycle}+5*t_{cycle}+6*t_{cycle}+6*t_{cycle})=4*(6+6+5+6+6)*t_{cycle}=16*6*20 ns+4*5*20 ns=2320 ns.

Using a long (multiple) modulation period enables the use of only one clock period instead of two. The different tₒₙ per period sums up into a better average resolution than possible with the single clock period. The example shows an average tₒₙ of 116 ms that never can be realized with a single 20 ns clock period.

The formula to get to the number of t_{period} periods within a long (multiple) modulation period t_{modulation} period that are needed for the resolution tᵣₑₛₒₗᵤₜᵢₒₙ=t_{cycle2}−t_{cycle1} is t_{cycle1}/(t_{cycle2}−t_{cycle1}).

Embodiments having different combinations of one or more of the features or steps described in the context of example embodiments having all or just some of such features or steps are intended to be covered hereby. Those skilled in the art will appreciate that many other embodiments and variations are also possible within the scope of the claimed invention.

What is claimed is:

1. A method for generating a pulse width modulated (PWM) signal, comprising:
determining a PWM period and/or a pulse width of the pulse width modulated signal by counting a number of clock cycles of a reference clock signal and by switching the pulse width modulated signal when a predetermined number of clock cycles is reached; wherein the reference clock signal comprises clock cycles of at least a first clock period and a second clock period, and the first clock period and the second clock period differ by an amount of time, which is substantially smaller than both half of the first clock period and half of the second clock period.

2. The method according to claim 1, further comprising:
generating a first clock signal having the first clock period, generating a second clock signal having the second clock period, and composing the reference clock signal by using at least one clock cycle of both the first clock signal and the second clock signal.

3. The method according to claim 1, wherein at least one clock cycle of the first period and one clock cycle of the second period are used within one period of the pulse width modulated signal.

4. The method according to claim 1, wherein the number of clock cycles having the first clock period and the number of clock cycles having the second clock period are selectively and variably chosen over a plurality of PWM periods of the pulse width modulated signal, such that the pulse width of the pulse width modulated signal is averaged over a plurality of PWM periods of the pulse width modulated signal.

5. The method of claim 1, wherein the number of clock cycles of the first clock period and the number of clock cycles of the second clock period is periodically varied over a modulation period.

6. An electronic device including circuitry for generating a pulse width modulated signal, the circuitry comprising:
a counter adapted to be increased in response to a reference clock signal;
a comparator for comparing the count of the counter to a predefined number;
a logic circuitry coupled to the counter output and to the comparator for producing the pulse width modulated signal;
a switch to switch the clock cycles of the reference clock signal between first clock cycles having a first clock period and second clock cycles having a second clock period, such that the first clock period and the second clock period differ by an amount of time which is substantially smaller than both half of the first clock period and half of the second clock period; and
a controlling means adapted to control the switching mechanism.

7. The electronic device according to claim 6, further comprising circuitry for setting the first clock period and the second clock period to differ by the amount of time which is substantially smaller than both half of the first clock period and half of the second clock period.

8. The electronic device according to claim 6, comprising circuitry for generating a first clock signal having the first clock period, generating a second clock signal having the second clock period.
